(19) United States
(12) Patent Application Publication
(10) Pub. No.: US 2013/0105214 A1
(43) Pub. Date: May 2, 2013

(54) METHOD FOR MANUFACTURING CIRCUIT BOARD PROVIDED WITH METAL POSTS AND CIRCUIT BOARD MANUFACTURED BY THE METHOD

(71) Applicant: SAMSUNG TECHWIN CO., LTD., Changwon-city (KR)

(72) Inventors: Soon Chul KWON, Seongnam-si (KR); Sang Min LEE, Seongnam-si (KR)

(73) Assignee: SAMSUNG TECHWIN CO., LTD., Changwon-city (KR)

(21) Appl. No.: 13/665,063

(22) Filed: Oct. 31, 2012

(30) Foreign Application Priority Data
Oct. 31, 2011 (KR) 10-2011-0111872

(51) Int. Cl. H05K 3/06; H05K 1/11; H05K 1/02

(52) U.S. Cl. CPC H05K 3/06; H05K 1/0296; H05K 1/115
USPC 174/266; 29/846; 174/250

(57) ABSTRACT

Provided is a method for manufacturing a circuit board provided with metal posts formed on at least one surface of the circuit board, the method including preparing a substrate made of a conductive material, performing a first selective etching a first surface of the substrate in regions corresponding to insulating portions of a first circuit pattern, laminating a first insulating layer over the first surface of the substrate, and performing a second etching on a second surface opposite of the first surface of the substrate, thereby forming the metal posts and the first circuit.

### CROSS-REFERENCE TO RELATED PATENT APPLICATION

This application claims priority from Korean Patent Application No. 2011-0111872 filed on Oct. 31, 2011 in the Korean Intellectual Property Office, the disclosure of which is incorporated herein by reference in its entirety.

### BACKGROUND

1. Field

The present invention relates to a method for manufacturing a circuit board, and more particularly to a circuit board formed with metal posts.

2. Description of the Related Art

In accordance with rapid development of the electronics industry, diverse technologies have recently been developed in fields related to electronic devices and circuit boards. In particular, in accordance with the recent trend of electronic products to be light, thin, simple, and miniature, there is increasing demand for packages formed with fine-pitch circuit patterns on a substrate and an increased number of input/output (I/O) terminals while having two or more different functions.

As a result, electrical connections between packages having different functions are changed from a wire bonding type to a flip chip type using solder balls to obtain a fine pitch and reliable electrical connections. For technologies related to packages having diverse functions, there are, for example, system-in-package (SIP), system-on-package (SOP), package-on-package (POP), and multi-chip package (MCP) technologies.

The POP technology is a package technology to integrate two semiconductor packages into a single package after an assembly of each package to provide a complete package structure. In accordance with the POP technology, there is a benefit of integrating different packages having different functions into a combined package. Since the integration is carried out after completion of electrical tests for the each package, there is also a benefit of reducing electrical errors generated after package integration.

There is the related art substrate manufacturing method as shown in FIGS. 1A-1F and FIGS. 2A-2D, where solder balls 1 are provided on pads 2 of a substrate. Also, there is another related art substrate manufacturing method as shown in FIGS. 3A-3I, where a substrate to be manufactured is provided with metal posts for a flip chip.

FIGS. 1A-1F and FIGS. 2A-2D are views illustrating the related art method for manufacturing a substrate having a solder-on-pad structure for a flip chip.

Hereinafter, one of the related art methods, in which a substrate with solder balls 1 is manufactured, will be described with reference to FIGS. 1A-2F and FIGS. 2A-2D. FIGS. 1A-1F illustrate a manufacturing method using a metal mask 3. In accordance with this method, the substrate provided with pads 2 is subjected to surface treatment (FIG. 1A), and the metal mask 3 is then aligned with the substrate (FIG. 1B). Thereafter, solders are printed on the pads 2 through the metal mask 3 (FIG. 1C). After removal of the metal mask 3 (FIG. 1D), a reflow process is carried out (FIG. 1E) to form the solder balls 1. Subsequently, a coining process may be carried out to make the solder balls 1 have a uniform height (FIG. 1F).

However, when the substrate, which has the solder-on-pad structure, is manufactured using the metal mask, as described above, there is a problem as follows.

FIGS. 4A-4B is a view showing solder balls abnormally formed in the related art manufacturing method of FIGS. 1A-1F to manufacture a substrate having a solder-on-pad structure for a flip chip.

As shown in FIGS. 4A and 4B, parts of the solder may be transferred to the metal mask 3 when the metal mask 3 is removed, such that the solder balls 1 may have non-uniform shapes (FIG. 4A). Also, since the solder fills the solder balls 1 through plating, the solder balls 1 completed through the reflow process may have non-uniform heights (FIG. 4B). For this reason, there may be a problem in that it may be necessary to perform an additional process such as coining to make the solder balls 1 have a uniform height.

Hereinafter, another solder-on-pad substrate manufacturing method will be described. FIGS. 2A-2D illustrate a micro-ball type manufacturing method of the related art. In accordance with the micro-ball type manufacturing method, a plurality of flux is printed on portions of a substrate corresponding to pads 2 (FIG. 2A). Thereafter, solder balls 1 are mounted on the pads 2 through a squeezing process (FIG. 2B).

However, the micro-ball type manufacturing method has a problem in that solder balls 1 may not be mounted on each of the pads 2 provided on the substrate. In order to solve this problem, it may be necessary to perform additional processes of checking whether or not the each of the pads 2 is mounted with a solder ball 1, and a rework process of mounting a solder ball 1 on a pad 2, on which no solder ball has been mounted, as shown in FIG. 2C. There is also a problem in that the overall process time is lengthened due to the additional processes.

In order to solve problems associated with the solder-on-pad substrate, a method for manufacturing a substrate provided with metal posts for a flip chip has been proposed. This method is disclosed in Korean Patent Application No. 10-2009-0094119.

FIGS. 3A-3I are views illustrating yet another related art method for manufacturing a substrate provided with metal posts for a flip chip, where the metal posts are formed through a plating method.

In accordance with this method, a non-conductive substrate with conductive pads 2 is first prepared (FIG. 3A), and a plating seed layer 5 is then formed on the conductive pads 2 (FIG. 3B). Thereafter, a dry film photoresist (DFR) layer 4, which is a photoresist film, is laminated over a resultant structure as shown in FIG. 3C. The resultant structure is then subjected to exposure and development processes (FIG. 3D), to expose the conductive pads 2. Subsequently, plating process is carried out to form metal posts 700 on the exposed conductive pads 2 (FIG. 3E). Thereafter, solder 500 is coated over the metal posts 700 before removal of the DFR layer 4, and the resultant structure is then subjected to a reflow process (FIG. 3F). A planarization process is also carried out with reference to the height of the DFR layer 4 (FIG. 3G). Finally, the DFR layer 4 and seed layer 5 are removed (FIG. 3H and FIG. 3I).

When the metal posts 700 are formed through plating, as described above, the plating process (FIG. 3E) is an essential process. However, the plating process may cause the following problem.

FIGS. 5A-5C are views illustrating metal posts abnormally formed through the related art method for manufacturing a substrate provided with metal posts for a flip chip.

FIG. 5B shows a metal post normally formed through plating. In the related art method using plating, however, there may be plating deviation. A metal post having a lower height than the normal metal post may be formed, as shown in FIG. 5A. Also, due to non-uniform plating, a metal post having a flattened shape different from the shape of the normal metal post may be formed, as shown in FIG. 5C. Due to such a problem, it may not be possible to electrically connect the package with another package having a function different from that of the former package.

### SUMMARY

One or more exemplary embodiments provide a method for manufacturing a circuit board provided with metal posts without using a separate plating process to form the metal posts, and the circuit board manufactured by the method.

In accordance with an aspect of an exemplary embodiment, there is provided a method for manufacturing a circuit board provided with metal posts formed on at least one surface of the circuit board including preparing a substrate made of a conductive material, performing a first selective etching on a first surface of the substrate in regions corresponding to insulating portions of a first circuit pattern, laminating a first insulating layer over the first surface of the substrate, and performing a second etching on a second surface opposite of the first surface of the substrate, thereby forming the metal posts and the first circuit.

The method may also include forming a second circuit pattern on the first surface of the substrate through an additive method between the laminating of the first insulating layer and the performing of the second etching.

The method may also include forming a second circuit pattern on the first surface of the substrate through an additive method, after the performing of the second etching.

The method may also include forming vias extending through the first insulating layer before the forming of the second circuit pattern.

The laminating of the first insulating layer may include forming the first insulating layer and a first conductive layer over the primarily-etched surface of the substrate and the method may also include forming a second circuit pattern on the first surface of the substrate through a subtractive method.

The first conductive layer may be formed simultaneously with the first insulating layer through a lamination method or is formed over the first surface of the substrate through electroless plating.

The method may also include forming a second circuit pattern on the first surface of the substrate through a subtractive method between the laminating of the first insulating layer and the performing of the second etching.

The performing of the second etching may include forming photoresist layers over the surfaces of the substrate, patterning the photoresist layers through selective exposure and development to correspond to the metal posts and the second circuit pattern and performing a third etching on the surfaces of the substrate in regions exposed through the photoresist layers to form the metal posts, the first circuit pattern and the second circuit pattern.

The forming the photoresist layers may include forming one of the photoresist layers over the second surface of the substrate, performing electrolytic plating over the first surface of the substrate and forming the other of the photoresist layers over the plated surface of the substrate.

The performing of the second etching may also include simultaneously removing the photoresist layers.

The method may also include forming vias extending through the first conductive layer and the first insulating layer before the forming of the second circuit pattern.

The method may also include laminating a second insulating layer over the first surface of the substrate and forming a third circuit pattern on the first surface of the substrate through an additive method.

The method may also include forming a second insulating layer and a second conductive layer over the first surface of the substrate and forming a third circuit pattern on the first surface of the substrate through a subtractive method.

In accordance with another aspect of the present invention, there is provided a circuit board provided with metal posts formed on at least one surface of the circuit board including a first circuit pattern formed on a first surface of the substrate on which the metal posts are formed, and an insulating layer disposed on a first surface the substrate formed with the first circuit pattern, the insulating layer protruding in regions corresponding to insulating portions of the first circuit pattern. The substrate is made of a conductive material. The circuit board may further include a second circuit pattern formed on an opposite surface of the substrate, and via holes formed to extend from the second circuit pattern through the insulating layer.

### BRIEF DESCRIPTION OF THE DRAWINGS

The above and/or other aspects of the disclosure will become apparent and readily appreciated from the following detailed description of exemplary embodiments taken in conjunction with the accompanying drawings of which:

FIGS. 1A-1F and FIGS. 2A-2D are views illustrating a related art method for manufacturing a substrate having a solder-on-pad structure for a flip chip;

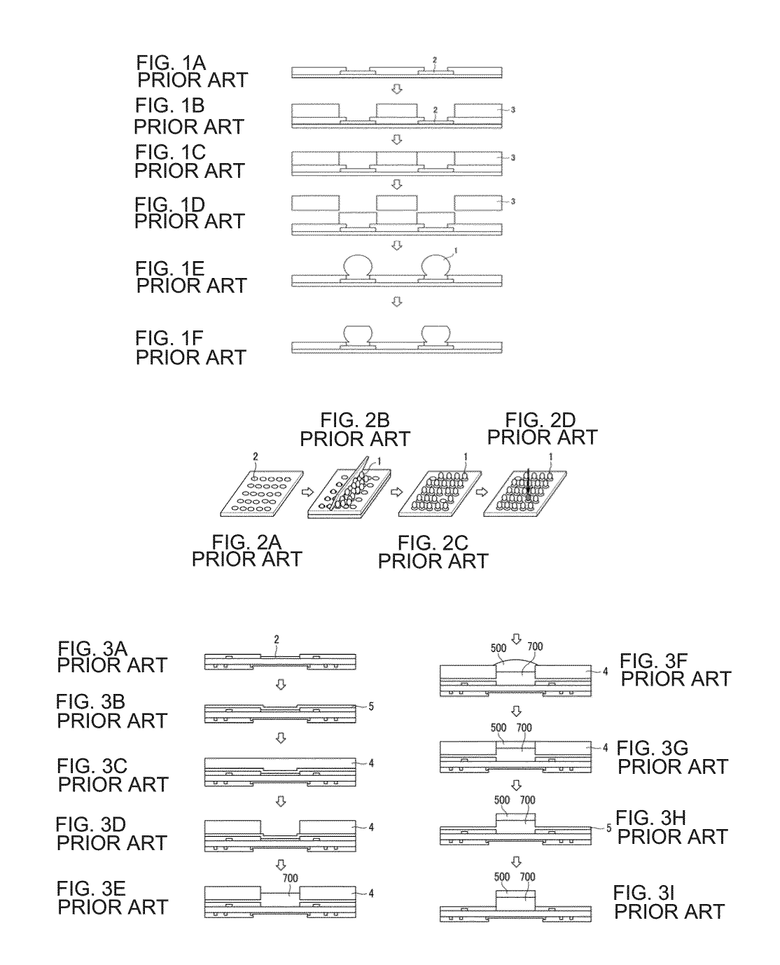

FIGS. 3A-3I are views illustrating a related art method for manufacturing a substrate provided with metal posts for a flip chip;

FIGS. 4A and 4B are views showing solder balls abnormally formed in the related art manufacturing method of FIG. 1A-1F to manufacture a substrate having a solder-on-pad structure for a flip chip;

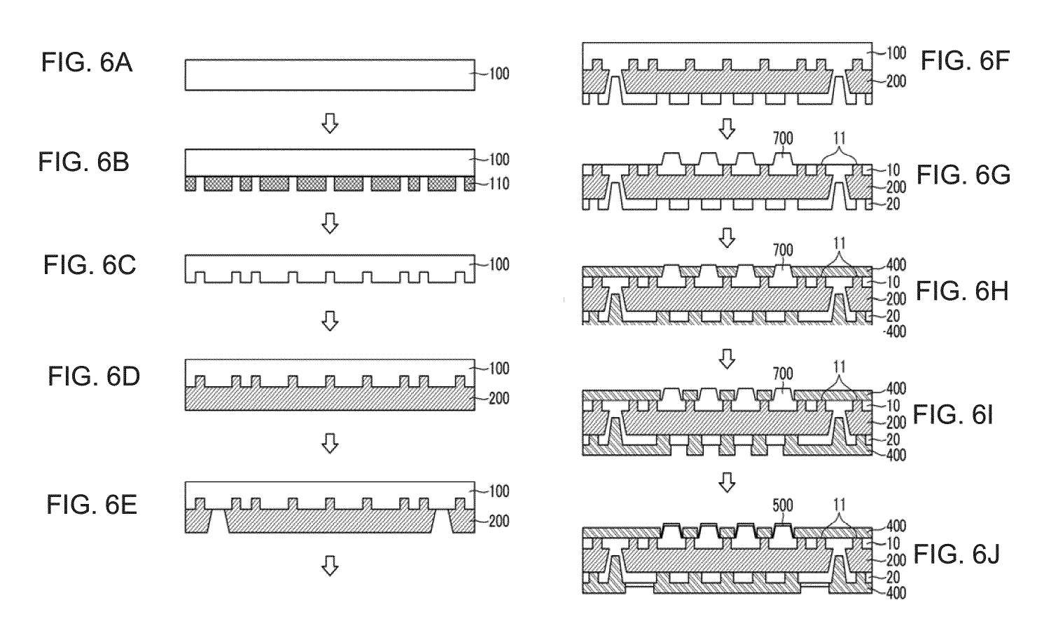

FIGS. 5A-5C are views showing metal posts abnormally formed through the related art method of FIGS. 3A-3I to manufacture a substrate provided with metal posts for a flip chip;

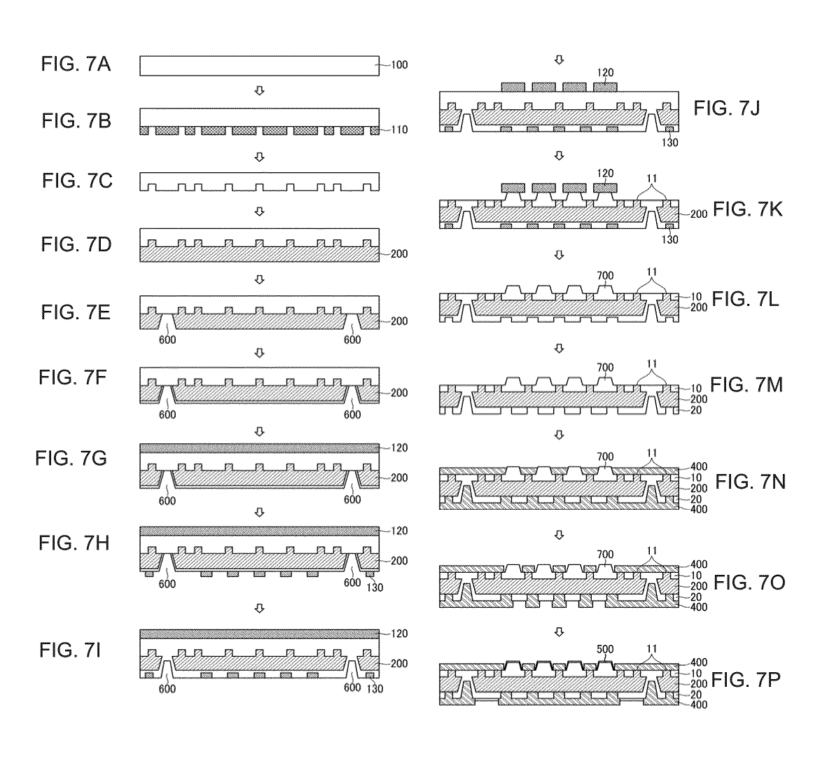

FIGS. 6A-6J and FIGS. 7A-7P are views illustrating a method of manufacturing a circuit board with metal posts, using an additive method, in accordance with an exemplary embodiment;

FIG. 8A is a flowchart illustrating the method of FIGS. 6A-6J;

FIG. 8B is a flowchart illustrating the method of FIGS. 7A-7P;

FIGS. 9A-9M are views illustrating a method of manufacturing a circuit board with metal posts, using a subtractive method, in accordance with another exemplary embodiment;

FIGS. 10A and 10B are flowcharts illustrating the method of FIGS. 9A-9M; and

FIGS. 11A and 11B are flowcharts illustrating a method of manufacturing a circuit board with multilayered metal posts in accordance with yet another embodiment.

### DETAILED DESCRIPTION

Hereinafter, exemplary embodiments will be described in detail with reference to the accompanying drawings, to enable a person having ordinary knowledge in the technical field to easily implement the exemplary embodiments. Like reference numerals refer to like elements throughout.

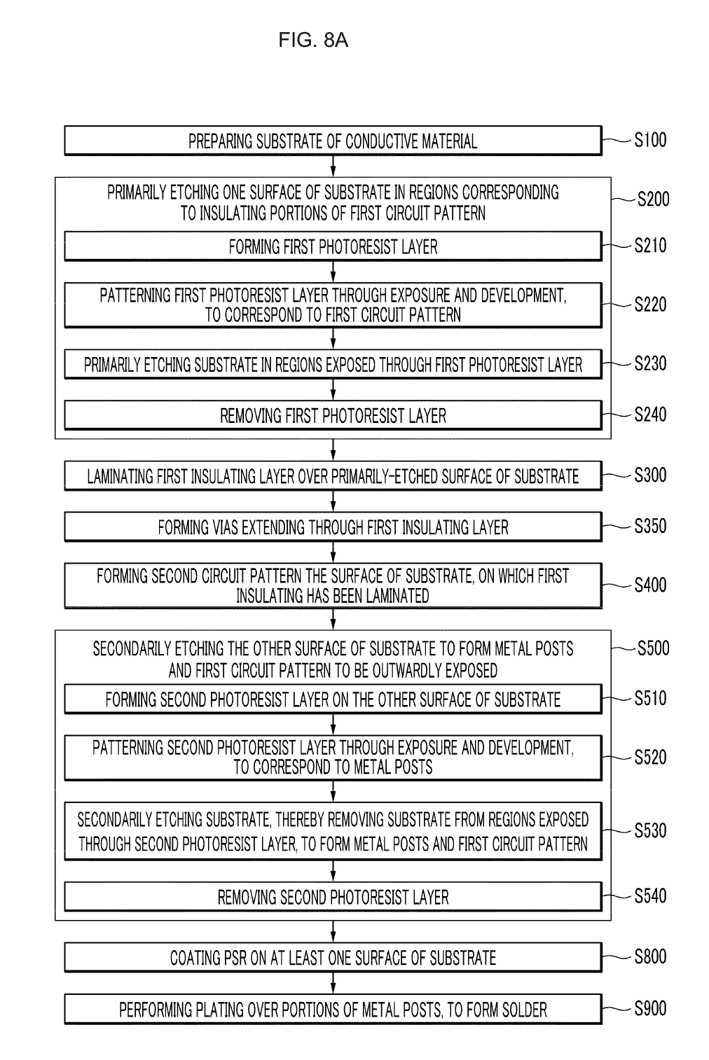

A circuit board with metal posts according to exemplary embodiments will be described hereinafter. A configuration of the circuit board is illustrated in FIGS. 6G, 7L, and 9J. That is, the circuit board includes, a substrate 100 (See FIG. 6C) formed with metal posts 700, a first circuit pattern 10 formed on one surface of the substrate 100, and an insulating layer 200 made of an insulating material such as a prepreg and disposed beneath the first circuit pattern 10. The insulating layer 200 is protruded through the first circuit pattern 10 in insulating regions of the first circuit pattern 10, thereby forming insulating portions 11 of the first circuit pattern 10. The metal posts 700 and the first circuit pattern 10 are formed as one surface of a substrate 100 made of a conductive material via etching and formed with an insulating layer. Thus, the metal posts 700 are integrated with conductive portions of the first circuit pattern 10. Since the metal posts 700 are formed without using a plating process, there is no formation of poor metal posts caused by non-uniformity of height or shape. Thus, it may be possible to form the metal posts having a uniform height and a uniform shape.

The circuit board with metal posts according to exemplary embodiments may further include a second circuit pattern 20 formed on the other surface of the substrate opposite to the surface, on which the first circuit pattern 10 and metal posts 700 are formed. Via holes 600 are formed to extend from the second circuit pattern 20 through the insulating layer. Each via hole 600 may be plated with a conductive material to electrically connect the first circuit pattern 10 and second circuit pattern 20.

Since the via holes 600 are formed to extend from the second circuit pattern 20, no dimple is formed on the second surface on which the first circuit pattern 10 and metal posts 700 are formed. Accordingly, the surface flatness of the substrate formed with the metal posts 700 can be increased.

Hereinafter, methods for manufacturing a circuit board with metal posts according to exemplary embodiments will be described.

The methods of manufacturing the circuit board with the metal posts according to the exemplary embodiments include the steps of preparing a substrate 100 made of a conductive material, primarily selectively etching one surface of the substrate 100 in regions corresponding to the insulating portions 11 of the first circuit pattern 10, laminating a first insulating layer 200 over the primarily-etched surface of the substrate 100, and secondarily etching the other surface of the substrate 100 such that the first circuit pattern 10 is outwardly exposed. In accordance with the exemplary methods, a coreless circuit board formed with a circuit pattern on one surface thereof is formed without using a plating process.

A second circuit pattern may be formed on the surface of the substrate 100 on which the first insulating layer 200 has been laminated. The formation of the second circuit pattern may be achieved using an additive method or a subtractive method. When the subtractive method is used, the step of laminating the first insulating layer 200 may include formation of a first conductive layer 300 in addition to the first insulating layer 200.

The formation of the second circuit pattern may be carried out before or after the secondary etching step. The formation of the via holes may be carried out before the formation of the second circuit pattern.

### First Exemplary Embodiment

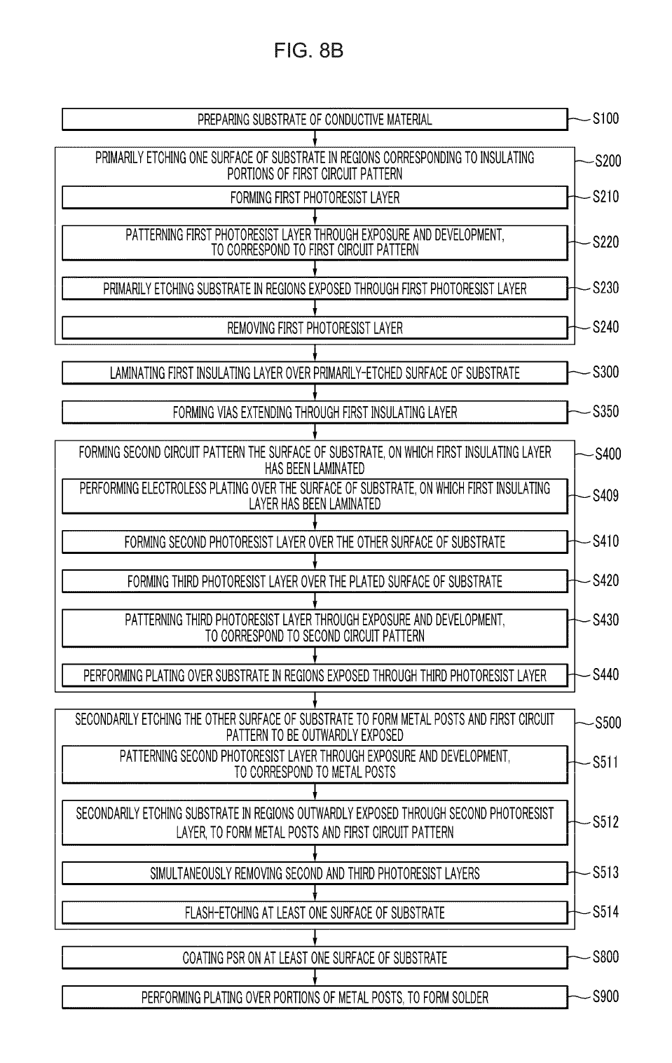

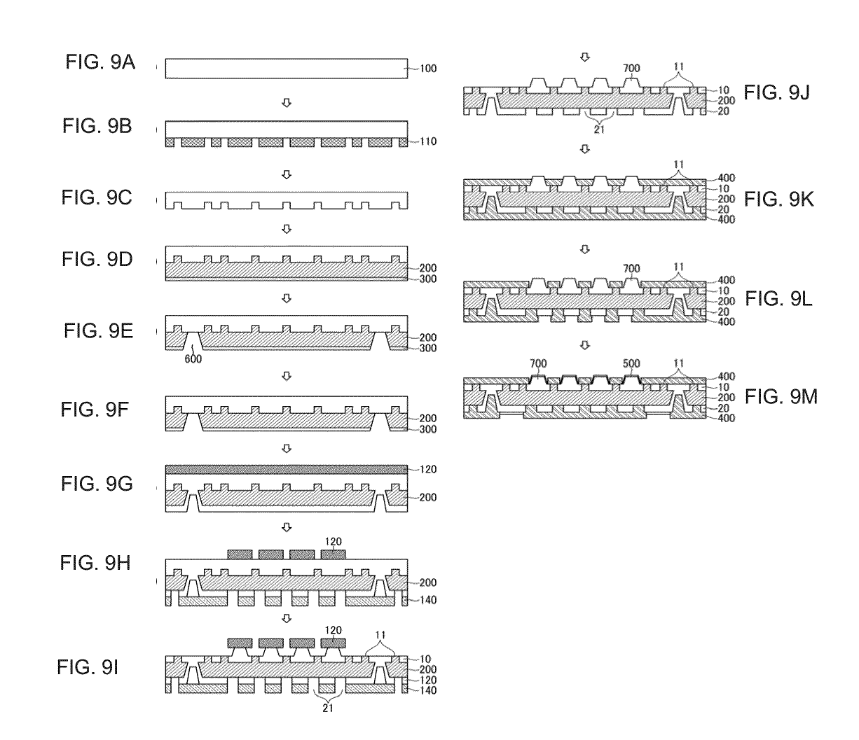

FIGS. 6 and 7 are views illustrating a method of manufacturing the circuit board with metal posts according to an exemplary embodiment, using an additive method. FIGS. 8A and 8B are flowcharts illustrating the method of FIGS. 6 and 7, respectively.

As shown in FIG. 8A, a method of manufacturing a circuit board with metal posts according to the current exemplary embodiment includes sequential steps of preparing a substrate 100 made of a conductive material (S100), primarily selectively etching a first surface of the substrate 100 on regions corresponding to insulating portions 11 of a first circuit pattern 10 (S200), laminating a first insulating layer 200 over the primarily-etched surface of the substrate 100 (S300), and secondarily etching a second surface opposite of the primarily-etched surface of the substrate 100 such that metal posts 700 and a first circuit pattern 10 are formed and outwardly exposed (S500). The current exemplary manufacturing method may also include the steps of forming vias extending through the first insulating layer 200 (S350), and forming a second circuit pattern 20 on the primarily-etched surface of the substrate 100 using an additive method (S400). The manufacturing method may further include steps of coating a photo solder resist (PSR) over at least one of the first and second surface of the substrate 100 (S800), and performing plating over the outwardly-exposed top or side surfaces of metal posts 700 to form a solder (S900).

Step S400 of forming the second circuit pattern 20 may be carried out before or after the secondary etching step. Step S350 of forming vias may be carried out before formation of the second circuit pattern 20, but after lamination of the first insulating layer 200.

As shown in FIG. 6A, the method of manufacturing the circuit board with metal posts according to the exemplary embodiment starts by preparing a substrate made of a conductive material.

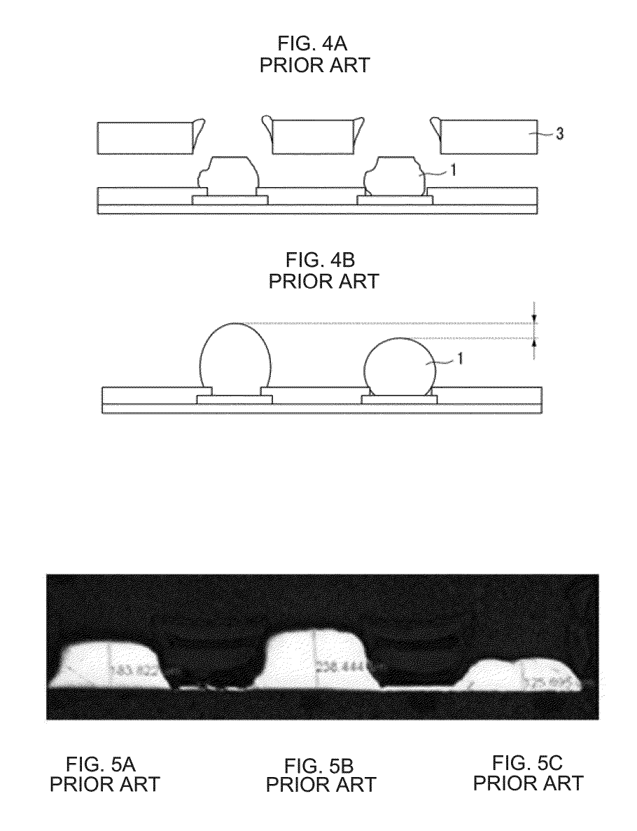

In the related art, as shown in FIGS. 3A-3I, metal posts are formed on a substrate using an insulating material, through a plating method. In the current exemplary embodiment, however, a substrate made of a conductive material is used without using a substrate made of an insulating material, as shown in FIG. 6A. Accordingly, it may be possible to form metal posts without using a plating process causing problems involved in the related art cases discussed earlier. It may also be possible to manufacture a coreless substrate in accordance with the manufacturing method according to the current exemplary embodiment. The conductive material of the substrate may be gold (Au), silver (Ag), copper (Cu) or the like. Preferably, the substrate is made of copper, which is effective in electrical and thermal conductivity characteristics and offers advantages in increase of productivity.

The next step of the manufacturing method according to this embodiment is step S200 of primarily selectively etching a first surface of the substrate 100 in regions corresponding to the insulating portions 11 of the first circuit pattern 10, as shown in FIGS. 6B and 6C.

The primary etching step S200 may include forming a first photoresist layer 110 over the first surface of the substrate 100 (S210), patterning the first photoresist layer 110 through selective exposure and development to correspond to the first circuit pattern 10 to be formed on a second surface opposite of the first surface of the substrate 100 (S220), and primarily etching the first surface of the substrate 100 from regions outwardly exposed through the patterned first photoresist layer 110 (S230). The primary etching step S200 may further include removing the first photoresist layer 110 (S240).

Hereinafter, the primary etching step S200 will be sequentially described in more detail. Step S210 of forming the first photoresist layer 110 over the first surface of the substrate 100 is illustrated in FIG. 6B. The first photoresist layer 110 laminated over the first surface of the substrate 100 may be made of photoresist such as a dry film photoresist (DFR), liquid photoresist (LPR) or electric deposit photoresist (EDPR). EDPR is preferable in that it may be possible to adjust a photoresist coating thickness through adjustment of voltage, temperature, and time. It may be possible to form the first photoresist layer 110 using DFR because it is unnecessary to form a photoresist layer on side walls of grooves, such as vias, formed on the substrate 100.

In the next step, the first photoresist layer 110 is selectively exposed to light, using a mask pattern (not shown) or a laser direct image (LDI) corresponding to the first circuit pattern 10. Subsequently, the partially-exposed first photoresist layer 110 is developed using a developing solution or the like. Thus, the first photoresist layer 110 is patterned as the light-exposed portions of the first photoresist layer 110 is removed (positive) or the light-unexposed portions of the first photoresist layer 110 is removed (negative) as shown in FIG. 6B.

Although the exposure process for the first photoresist layer 110 may be achieved using either the method of using a mask pattern or the method of using the LDI, as described above, the exposure process using the LDI method is preferable in that it may be possible to form a micro circuit having high resolution at high rate without a separate mask. Further, there is no possibility of formation of poor products caused by foreign matter on a mask because, in accordance with the LDI method, desired portions of the photoresist layer are selectively exposed to light through irradiation of a laser based on data set in a computer.

Finally, the portions of the substrate 100 outwardly exposed through the first photoresist layer 110 are primarily etched (S230). As a result, the portions of the substrate 100 corresponding to regions corresponding to the insulating portions 11 of the first circuit pattern 10 are removed, thereby forming grooves on the substrate 100, as shown in FIG. 6C. Subsequently, the first insulating layer 200 is laminated over the resultant structure such that the first insulating layer 200 fills the grooves. As the substrate 100 is etched on a second surface thereof opposite to the first surface, on which the first insulating layer 200 has been laminated, the first circuit pattern 10 is outwardly exposed. Thus, the first circuit pattern 10 is formed.

After formation of the first circuit pattern 10, the first photoresist layer 110 is removed from the substrate 100 in accordance with a peel-off process (S240).

As shown in FIG. 6D, the next step of the manufacturing method according to this embodiment is step S300 of laminating the first insulating layer 200 over the primarily-etched surface of the substrate 100, where the first circuit pattern 10 is formed as grooves corresponding to the insulating portions 11 of the first circuit pattern 10 are formed on the substrate 100 by the primary etching process, and the first insulating layer 200 is then laminated to a desired thickness over the substrate 100, to fill the grooves. As the first insulating layer 200 is laminated over the substrate 100, the substrate 100 having the first circuit pattern 10 has a coreless substrate structure.

For the material of the first insulating layer 200, it is preferable to use a prepreg of a semi-cured state formed by penetrating a thermosetting resin into glass fibers to provide heat resistance, copper film bonding force, and high permittivity.

The manufacturing method according to the current exemplary embodiment may include, as the next step, step S350 of forming, on a first surface of the substrate 100, vias extending through the first insulating layer 200, as shown in FIG. 6E.

The vias may have a blind via hole (BVH) structure extending only through the first insulating layer 200. In the current exemplary embodiment, the via holes 600 may be formed using a mechanical drill such as a computer numerical control (CNC) drill or a laser drill.

The manufacturing method according of the exemplary embodiment may further include additional processes carried out after the formation of the via holes 600, such as a deburring process to remove debris particles attached to inner surfaces of the via holes 600, and debris, fingerprints, etc. attached to the surfaces of the thin films, and a desmear process to remove smears formed as resin of the first insulating layer 200 is first melted during the formation of the via holes 600 and then attached to the inner surfaces of the via holes 600.

Although either the mechanical drill or the laser drill may be applicable, the laser drill is preferable for rapid formation of fine and delicate holes.

During the next step of the manufacturing method according to this embodiment is step S400 of forming the second circuit pattern 20 on the surface of the substrate 100 on which the first insulating layer 200 has been laminated, the method of forming the second circuit pattern 20 may be performed by a subtractive method or an additive method.

In the subtractive method, a copper-laminated plate is etched, for formation of a circuit, on portions of the copper-laminated plate other than portions to be formed with the circuit. The subtractive method may include a tenting method, a panel/pattern method, etc.

In the tenting method, after laminating a conductive layer over a substrate, or subjecting the substrate to electroless plating or electrolytic plating, a photoresist is coated over the resultant structure of the substrate and the conductive layer. Thereafter, the coated photoresist is subjected to exposure and development processes, to form a photoresist pattern. Using the patterned photoresist as a mask, the structure is etched. Subsequently, the photoresist is removed to complete a circuit.

In the panel/pattern method, after laminating a conductive layer over a substrate, or subjecting the substrate to electroless plating or electrolytic plating, a photoresist is coated over the resultant structure of the conductive layer and the substrate. Thereafter, the coated photoresist is subjected to exposure and development processes, to form a photoresist pattern. Electrolytic plating is then carried out to form a patterned plated layer. After removal of the photoresist, the resultant structure is etched to complete a circuit.

In the additive method, a circuit is formed on an insulating layer using plating or the like. The additive method may include, for example, a semi-additive (SAP) method, a modified semi-additive (MSAP) method, an advanced modified semi-additive (AMSAP) method, and a full-additive (FAP) method.

The SAP, MSAP, and AMSAP methods are similar. After electroless plating is carried out over a substrate, a photoresist is coated over the resultant structure. Thereafter, the coated photoresist is subjected to exposure and development processes, to form a photoresist pattern. Electrolytic plating is then carried out to form a patterned plated layer. After removal of the photoresist, the resultant structure is etched to complete a circuit.

In the FAP method, after coating a photoresist over a substrate, the coated photoresist is subjected to exposure and development processes, to form a photoresist pattern. Electroless plating is then carried out over the resultant structure with the patterned photoresist, to complete a circuit.

The second circuit pattern 20 may be formed using the subtractive method or additive method. In the current exemplary embodiment, the tenting method, panel/pattern method, or the like may be used as the subtractive method, whereas the SAP, MSAP, AMSAP, or FAP method may be used as the additive method.

After completion of forming the second circuit pattern 20 using the subtractive method or additive method, the second circuit pattern 20 is formed on a second surface opposite of the first surface on which the first insulating layer is laminated of the substrate 100, as shown in FIG. 6F. The details of this procedure will be described in conjunction with a second exemplary embodiment.

During the next step of secondarily etching the substrate 100 to form the metal posts 700 on the second surface of the substrate 100 and to outwardly expose the first circuit pattern 10, the metal posts 700 are formed by the substrate 100 made of a conductive material. Preferably, the metal posts 700 are made of copper (Cu). In accordance with formation of the metal posts 700, an increased shear strength is exhibited during connection of a resultant package to another package. Thus, mechanical reliance may be secured. Also, in the case of a fine-pitch circuit, anti-bridge between adjacent solders may be secured. Thus, reliance of electrical mounting may also be secured.

The second etching step S500, at which the metal posts 700 and first circuit pattern 10 are formed to be outwardly exposed, may include the steps of forming a second photoresist layer 120 over the second surface opposite of the first surface on which the first insulating layer is laminated of the substrate 100 (S510), patterning the second photoresist layer 120 through selective exposure and development, to correspond to the metal posts (S520), and secondarily etching the substrate 100 from regions outwardly exposed through the patterned second photoresist layer 120, to form the metal posts and first circuit pattern 10 (S530) as shown in FIGS. 7A-7P.

Steps S510, S520, and S530 are similar to those of the primary etching step using the first photoresist layer and, as such, no detailed description will be given of those steps.

Through the above-described procedure, the metal posts 700 and the first circuit pattern 10 are simultaneously formed on the second surface opposite of the first surface on which the first insulating layer is laminated of the substrate 100.

The manufacturing method of the current exemplary embodiment may further include step S440 of removing the second photoresist layer 120 from the substrate 100 through a peel-off process. In the current embodiment, the second photoresist layer 120 may be removed immediately after the secondary etching step, or may be subsequently removed together with a photoresist layer used at step S400 of forming the second circuit pattern 20.

The manufacturing method of the exemplary embodiment may further include step S800 of coating a photo solder resist (PSR) 400 over on least one surface of the first and second surface of the substrate 100, as shown in FIG. 61.

Treatment for surface protection of the substrate 100 may be achieved through coating of the PSR 400. The PSR 400 may be of a liquid type or a dry film type.

In coating the liquid type PSR as well as the case of coating the dry film type PSR, the metal posts 700 formed on at least one of the first and second surface of the substrate 100 are partially exposed without being completely covered by the PSR 400, whereas the rest of the surface of the substrate 100 is completely covered by the PSR 400. When the PSR 400 is coated over the surfaces of the substrate 100, the surface flatness on the surface of the substrate, on which the metal posts 700 are formed and on which a chip will be bonded, is enhanced because no via hole is formed on the chip-side surface of the substrate, and the first circuit pattern 10 is not protruded from the chip-side surface of the substrate such that the first circuit pattern 10 has a buried pattern structure. Thus, when filling of a resin is carried out after bonding the chip on the substrate 100, the resin is smoothly penetrated into the substrate, thereby enhancing reliance of boding of the chip to the substrate.

In order to outwardly expose the side walls of the metal posts 700, to which bonding of the chip will be carried out, the PSR 400 is subjected to exposure and development processes using a laser direct image. In the laser direct image process, a patterned PSR protection layer may be formed. Otherwise, the PSR 400 may be partially removed through a laser direct ablation (LDA) method without using an exposure process, to form a patterned PSR protection layer. Although patterning of the PSR may be achieved using any of the above-described methods, the LDA method is preferable for process simplification since the LDA method does not require a separate development process. Also, when the exposure is carried out in a non-contact exposure manner, a divisional exposure method is preferable to minimize of exposure toleration.

The manufacturing method according to the current exemplary embodiment may include, as the next step, step S900 of forming a solder 500 on the outwardly-exposed top or side surfaces of the metal posts 700, as shown in FIG. 6J.

The solder 500 may be formed on the top side or the side surfaces of the metal posts 700, from which the PSR 400 has been removed, through tin plating. Plating of tin, which is similar to the material of solder balls (not shown), is preferable in that it may be possible to increase the bonding force to the solder balls.

### Second Exemplary Embodiment

The second exemplary embodiment illustrates a method for manufacturing a circuit board with metal posts, in which a second circuit pattern 20 is formed through an additive method.

As shown in FIG. 8B, the method of manufacturing the circuit board with the metal posts according to the second exemplary embodiment includes sequential steps of preparing a substrate 100 made of a conductive material (S100), primarily selectively etching a first surface of the substrate 100 in regions corresponding to insulating portions 11 of a first circuit pattern 10 (S200), laminating the first insulating layer 200 over the primarily-etched surface of the substrate 100 (S300), forming a second circuit pattern 20 on the first surface of the substrate 100 on which the first insulating layer 200 has been laminated using an additive method (S400), and secondarily etching a second surface opposite of the first surface of the substrate 100 on which the first insulating layer 200 has been laminated such that metal posts 700 and the first circuit pattern 10 are outwardly exposed (S500). The manufacturing method may further include steps of coating a PSR over at least one surface of the substrate 100 (S800), and performing plating over the outwardly-exposed top or side surfaces of metal posts 700, to form a solder (S900).

The method of manufacturing the circuit board with metal posts according to the second exemplary embodiment may further include the step of forming vias extending through the first insulating layer 200 after lamination of the first insulating layer 200 over the primarily-etched surface of the substrate 100 (S300).

In the following description, no description will be given of contents overlapped with those of the first embodiment, and only the steps different from those of the first embodiment will be described in detail with reference to FIGS. 7A-7P.

As shown in FIGS. 7F to 7I, step S400 of forming the second circuit pattern 20 on the first surface of the substrate 100, on which the first insulating layer 200 has been laminated, may include the steps of performing electroless plating over the first surface of the substrate 100, on which the first insulating layer 200 has been laminated (S409), forming a second photoresist layer 120 over the second surface opposite of the first surface of the substrate 100 (S410), forming a third photoresist layer 130 over the plated surface via the eletroless plating of the substrate 100 (S420), patterning the third photoresist layer 130 through selective exposure and development, to correspond to the second circuit pattern 20, and performing plating over the substrate in regions exposed through the third photoresist layer 130.

The electroless plating is performed over the first surface of the substrate 100, at which via holes extending through the first insulating layer 200 (FIG. 7F), and the second photoresist layer 120 is formed over the entire portion of the second surface opposite of the first surface of the substrate 100 (FIG. 7G[[G]]) to prevent the second surface of the substrate 100 from being plated with a plating material when plating is performed over the first surface of the substrate 100 in the regions exposed through the third photoresist layer 130, to correspond to the second circuit pattern 20 (FIGS. 7H and 7I).

The sequence of step S510 of forming the second photoresist layer 120 and step S520 of forming the third photoresist layer 130 may be reversed.

As shown in FIGS. 7J to 7L, step S500 of secondarily etching the other surface of the substrate 100 such that the metal posts 700 and first circuit pattern 10 are formed to be outwardly exposed may include the steps of patterning the second photoresist layer 120 through selective exposure and development, to correspond to the metal posts 700 (S511), secondarily etching the substrate 100 in regions outwardly exposed through the patterned second photoresist layer 120, thereby removing corresponding portions of the substrate 100 and outwardly exposing corresponding portions of the first insulating layer 200, to form the metal posts 700 and first circuit pattern 10 (S512), simultaneously removing the second photoresist layer 120 and third photoresist layer 130 (S513), and flash-etching at least one of the first and second surfaces of the substrate 100 (S514).

As the second photoresist layer 120 and third photoresist layer 130 are simultaneously removed in a single peel-off process, it may be possible to reduce the number of processing steps.

As a thin plating layer formed on the first surface of the substrate 100, on which the third photoresist layer 130 has been formed, is removed through flash etching (S514), the second circuit pattern 20 is completed.

Although the current exemplary embodiment illustrates a method in which the second circuit pattern 20 is formed through an additive method, the exemplary embodiment is not limited thereto.

### Third Exemplary Embodiment

The third exemplary embodiment illustrates a method of manufacturing a circuit board with metal posts, in which a second circuit pattern 20 is formed through a subtractive method.

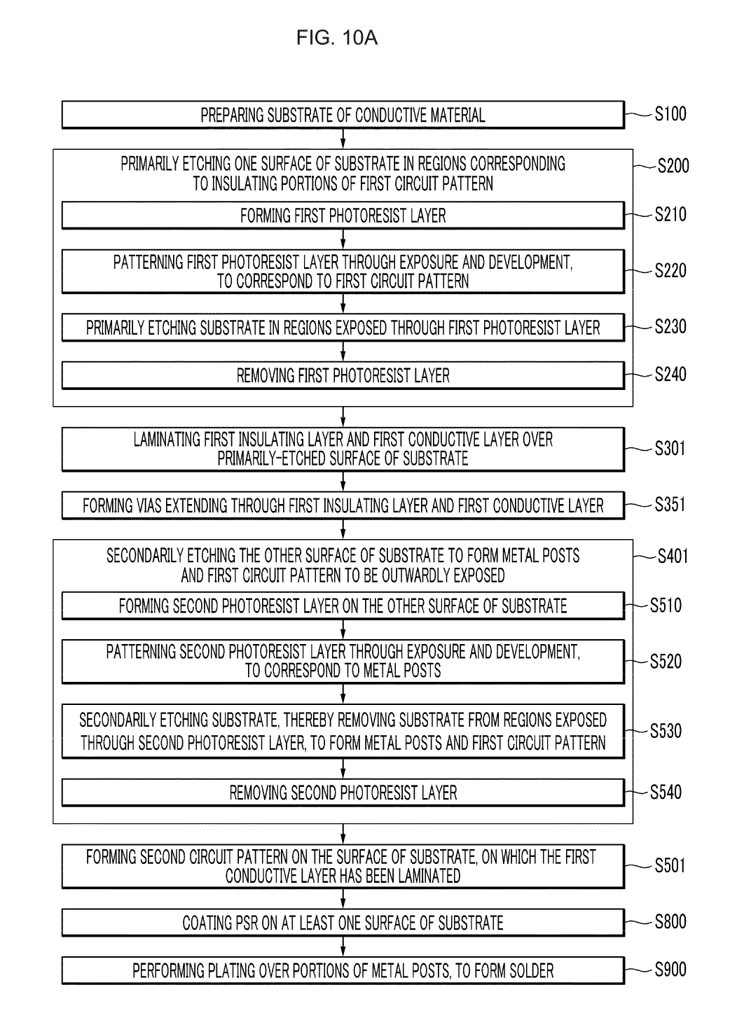

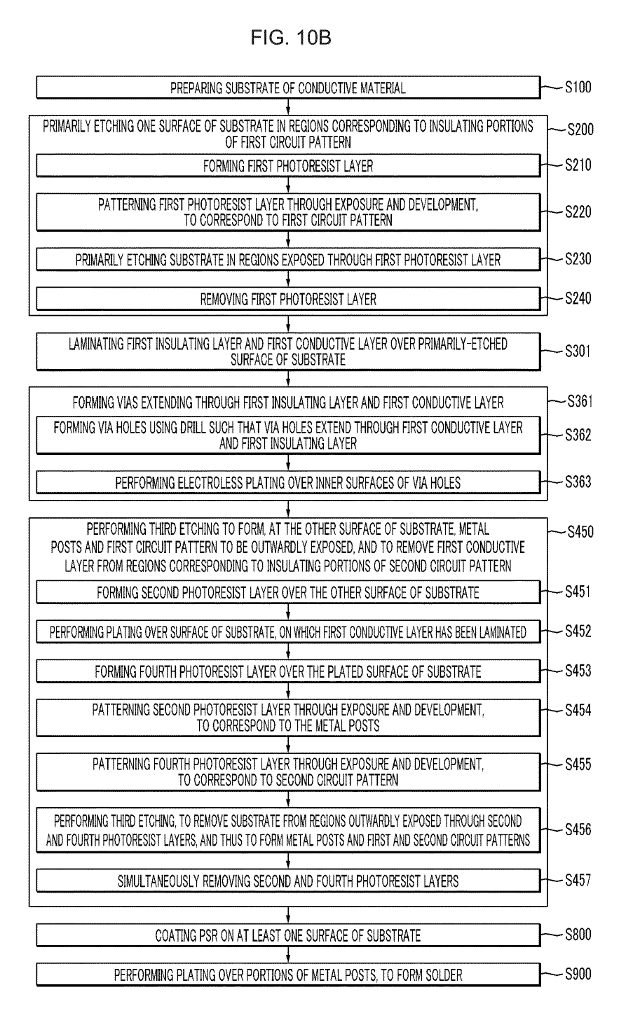

FIGS. 9A-9M are views illustrating the method of manufacturing the circuit board with metal posts according to the exemplary embodiment using a subtractive method. FIGS. 10A and 10B are flowcharts illustrating the method illustrated in FIGS. 9A-9M.

As shown in FIG. 10A, the method of manufacturing the circuit board with the metal posts according to the exemplary embodiment includes sequential steps of preparing a substrate 100 made of a conductive material (S100), primarily selectively etching a first surface of the substrate 100 in regions corresponding to insulating portions 11 of a first circuit pattern 10 (S200), sequentially laminating a first insulating layer 200 and a first conductive layer 300 over the primarily-etched surface of the substrate 100 (S301), secondarily etching a second surface opposite of the first surface of the substrate 100 such that metal posts 700 and a first circuit pattern 10 are outwardly exposed (S401), and forming a second circuit pattern 20 on the first surface of the substrate 100, on which the first conductive layer 200 has been laminated (S501). The manufacturing method may also include the steps of coating a PSR 400 over at least one of first and second surface of the substrate 100 (S800), and performing plating over the outwardly-exposed top or side surfaces of metal posts 700 to form a solder (S900).

The order of secondary etching step S401 of forming the first circuit pattern 10 and step S501 of forming the second circuit pattern may be reversed. Also, the metal posts 700, the first circuit pattern 10 and the second circuit pattern 20 may be simultaneously formed as the first and second surfaces of the substrate 100 are simultaneously etched in the secondary etching step S401.

Also, the method of manufacturing the circuit board with metal posts according to the exemplary embodiment may further include step S351 of forming vias extending through the first insulating layer 200 and first conductive layer 300 after sequentially laminating the first insulating layer 200 and first conductive layer 300 over the primarily-etched surface of the substrate 100 to form the vias (S300), but before the formation of the second circuit pattern.

Each step of the method of manufacturing a circuit board with metal posts, in which the second circuit pattern 20 is formed through a subtractive method in the current exemplary embodiment, is similar to the corresponding step of the first embodiment or second embodiment. That is, step S401 of secondarily etching the other surface of the substrate 100 such that metal posts 700 and the first circuit pattern 10 are formed to be outwardly exposed may include the steps of forming the second photoresist layer 120 over the second surface opposite of the first surface of the substrate 100 (S510), patterning the second photoresist layer 120 through exposure and development, to correspond to the metal posts 700 (S520), secondarily etching the substrate 100 in regions exposed through the patterned second photoresist layer 120, thereby removing corresponding portions of the substrate 100, to form the metal posts 700 and first circuit pattern 10 (S530), and removing the second photoresist layer 120 (S540).

The method of the current exemplary embodiment, in which the second circuit pattern 20 is formed through the subtractive method, is different from the first and second embodiments in that the first conductive layer 300 is formed over the first insulating layer 200 before the formation of the second circuit pattern 20 because the second circuit pattern 20 is formed on the first surface of the substrate, on which the first conductive layer 300 has been laminated.

The first conductive layer 300 may be formed simultaneously with the first insulating layer 200 through a lamination process. Alternatively, the first conductive layer 300 may be formed over the first surface of the substrate 100, on which the first insulating layer 200 has been formed, through electroless plating. When the first conductive layer 300 and first insulating layer 200 are simultaneously formed, an etching process may be further performed for thickness adjustment.

Although formation of the second circuit pattern 20 through the subtractive method may be achieved using the tenting method or panel/pattern method, the following description will be given of an embodiment in which the second circuit pattern 20 is formed using the tenting method.

FIG. 10B is a flowchart illustrating formation of the second circuit 20 pattern using the tenting method.

As shown in FIG. 10B, the method of manufacturing the circuit board with metal posts according to the exemplary embodiment includes sequential steps of preparing a substrate 100 made of a conductive material (S100), primarily selectively etching a first surface of the substrate 100 in regions corresponding to insulating portions 11 of a first circuit pattern 10 (S200), sequentially laminating a first insulating layer 200 and a first conductive layer 300 over the primarily-etched surface of the substrate 100 (S301), performing third etching to form metal posts 700 and the first circuit pattern 10 on a second surface opposite of the first surface of the substrate 100 such that metal posts 700 and the first circuit pattern 10 are outwardly exposed, and to remove the first conductive layer 330 from regions corresponding to insulating portions 21 of a second circuit pattern (S450), coating a PSR 400 over at least one of the first and second surface of the substrate 100 (S800), and performing plating over the outwardly-exposed top or side surfaces of metal posts 700, to form a solder (S900).

Hereinafter, each step of the above-described manufacturing method will be described in detail with reference to FIGS. 9A-9M.

As shown in FIGS. 9A-9M, the method of manufacturing the circuit board with metal posts according to the current exemplary embodiment includes step S100 of preparing the substrate made of a conductive material (FIG. 9A) and step S200 of primarily selectively etching a first surface of the substrate in regions corresponding to the insulating portions 11 of the first circuit pattern 10 (FIGS. 9B and 9C). However, these steps are identical to those of the first embodiment and, as such, no detailed description thereof will be given.

At the next step of the manufacturing method according to the current exemplary embodiment, the first insulating layer 200 and first conductive layer 300 are sequentially laminated over the primarily-etched surface of the substrate (S301). Although the first insulating layer 200 and first conductive layer 300 may be separately laminated, simultaneous lamination thereof is preferable in that it may be possible to reduce the number of processing steps.

The lamination of the first insulating layer 200 and first conductive layer 300 is carried out through pressing. As a result, the first insulating layer 200 fills grooves formed during the primary etching step. In place of the lamination method, electroless plating or electrolytic plating may be used to form the first conductive layer 300 over the first insulating layer 200. However, lamination through pressing is preferable for formation of the first conductive layer 300 in that it may be possible to increase the contact force between the first conductive layer 300 and the first insulating layer 200 and to reduce processing cost through process simplification. Another etching process may be carried out to adjust the thickness of the first conductive layer 300.

At the next step of the manufacturing method according to the exemplary embodiment, the metal posts 700 and first circuit pattern 10 are formed through secondary etching, or the second circuit pattern 20 is formed through a subtractive method. Another etching process may also be carried out to selectively remove the first conductive layer 300 from regions corresponding to the insulating portions 21 of the second circuit pattern 20, simultaneously with the formation of the metal posts 700 and first circuit pattern 10 on the second surface opposite of the surface of the substrate 100 such that the metal posts 700 and first circuit pattern 10 are outwardly exposed (S450), as shown in FIGS. 9G to 9J.

In more detail, the additional step S450 may include the steps of forming a second photoresist layer 120 over the second surface opposite of the first surface of the substrate 100 (S451), performing plating over the first surface of the substrate 100, on which the first conductive layer has been laminated (S452), forming a fourth photoresist layer 140 over the plated surface of the substrate 100 (S453), patterning the second photoresist layer 120 through selective exposure and development to correspond to the metal posts (S454), patterning the fourth photoresist layer 140 through selective exposure and development to correspond to the second circuit pattern 20 (S455), and performing third etching to remove the substrate 100 from regions outwardly exposed through the patterned second photoresist layer 120 and patterned fourth photoresist layer 140, and thus to form the metal posts 700 and the first and second circuit patterns 10 and 20 (S456). The manufacturing method may further include step S452 of performing electrolytic plating over the first surface of the substrate 100, on which the first conductive layer 300 has been laminated, after formation of the second photoresist layer 120 (S451).

The formation of the second and fourth photoresist layers 120 and 140 and the exposure and development of the second and fourth photoresist layers 120 and 140 are identical to those of the first exemplary embodiment. Preferably, the second photoresist layer 120 is laminated over the second surface of the substrate 100 (S451), prior to step S452 of performing electrolytic plating over the surface of the substrate 100, on which the first conductive layer 300 has been formed to apply plating only to the first surface of the substrate 100, and thus to protect the second surface of the substrate 100.

At the third etching step S450, the second and fourth photoresist layers 120 and 140 are formed in an order such that the second photoresist layer 120 is formed over the second surface of the substrate 100 (S451) prior to forming of the fourth photoresist layer 140 over the plated surface of the substrate (S453), and selective exposure and development is carried out for the second and fourth photoresist layers, in an order such that patterning the second photoresist layer 120 through exposure and development occurs (S454) prior to patterning the fourth photoresist layer 140 through exposure and development (S455). However, the order of exposure and development for the second and fourth photoresist layers (S454 and S455) may be reversed such that the exposure and development for the fourth photoresist layer precedes the exposure and development for the second photoresist layer in that there is no significant influence on the method of manufacturing the circuit board with metal posts according to the exemplary embodiment.

The electrolytic plating step S452 is carried out to form a conductive layer 300 before formation of the second circuit pattern 20 through etching. When via holes 600 are formed, a conductive layer 300 may also be formed on the inner surface of the via holes 600, for electrical connection of the via holes 600. In the exemplary embodiment, electroless plating (S363) may be carried out after the formation of via holes 600.

Although the second photoresist layer 120 and fourth photoresist layer 140 may be separately removed through peel-off processes, the second photoresist layer 120 and fourth photoresist layer 140 may be simultaneously peeled off from the substrate 100 to prevent the number of processing steps from being unnecessarily increased (S457).

Through the circuit formation using the tenting method, the second circuit pattern 20 is formed on a first surface of the substrate 100, and the metal posts 700 and first circuit pattern 10 are formed on a second surface opposite of the first of the substrate 100.

The manufacturing method according to the exemplary embodiment may further include the step of forming, on the first surface of the substrate 100, vias extending through the first conductive layer 300 and first insulating layer 200 after step S301 of sequentially laminating the first insulating layer 200 and first conductive layer 300, but before the third etching step S450, as shown in FIGS. 9E and 9F.

The via forming step S361 may include the steps of forming via holes using a mechanical drill or a laser drill such that the via holes 600 extend through the first conductive layer 300 and first insulating layer 200 (S362), and performing electroless plating over the inner surfaces of the via holes 600 (S363).

Step S362 of forming the via holes 600 using a mechanical drill or a laser drill is identical to that of the first embodiment and, as such, no detailed description thereof will be given.

At the electroless plating step S363 for the inner surfaces of the via holes 600, a conductive layer 300 is formed for electrical connection because the inner surfaces of the via holes 600 are made of an insulating material such as a prepreg.

The manufacturing method according to the exemplary embodiment may further include, as next steps, steps of coating a PSR over at least one of the first and second surface of the substrate 100 (S800), and performing plating over the outwardly-exposed top and side surfaces of the metal posts 700, to form a solder (S900).

The PSR coating step S800 and solder forming step S900 are identical to those of the first embodiment and, as such, no detailed description thereof will be given.

### Fourth Exemplary Embodiment

The forth exemplary embodiment illustrates a method for manufacturing a circuit board with metal posts, in which a triple-layered circuit structure is formed.

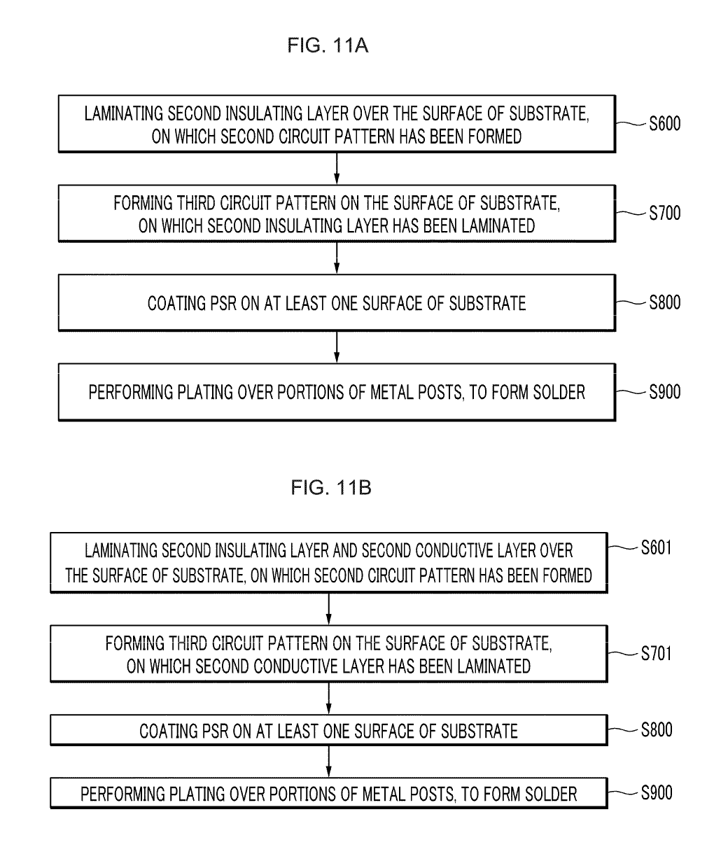

Referring to FIG. 11A, the triple-layered circuit board may be manufactured by performing steps of additionally laminating a second insulating layer (not shown) over the surface of the substrate 100, on which the second circuit pattern 20 has been formed, before coating of the PSR 400 (S600), and forming a third circuit pattern on the surface of the substrate 100, on which the second insulating layer has been laminated, through an additive method such as a SAP, MSAP, AMSAP, or FAP (S700) on a double-layered circuit board formed in the first or second embodiment as shown in FIG. 6F, 7M, or 9J.

Alternatively, as shown in FIG. 11B, the triple-layered circuit board may be manufactured by performing steps of sequentially additionally laminating a second insulating layer (not shown) and a second conductive layer (not shown) over the surface of the substrate 100, on which the second circuit pattern 20 has been formed, before coating of the PSR 400 (S601), and forming a third circuit pattern on the surface of the substrate 100, on which the second conductive layer 310 has been laminated, through a tenting method or a panel/pattern method (S701) on a double-layered circuit board formed in the third embodiment.

The second insulating layer corresponds to the first insulating layer 200, and the second conductive layer corresponds to the first conductive layer 300. Accordingly, the triple-layered circuit board may be manufactured using the same method as that of first to third embodiment.

Although a method of manufacturing a triple-layered circuit board is illustrated in the current exemplary embodiment, a circuit board with a multilayered circuit structure of four or more circuit layers may be manufactured through repetition of the above-described processing steps.

The above-described methods of manufacturing a circuit board with metal posts according to the exemplary embodiments provide an effect of avoiding formation of poor metal posts caused by non-uniformity of height or shape because the metal posts are formed at a substrate having conductivity, through etching.

Also, the method of manufacturing a circuit board with metal posts according to the exemplary embodiment provides a benefit of avoiding failure of electrical connection during assembly of the associated package with another package because metal posts having a uniform shape are formed without non-uniformity of height or shape.

The method of manufacturing a circuit board with metal posts according to the exemplary embodiments also provides a benefit of avoiding formation of dimples on the second surface of the substrate, on which the metal posts are formed, in that no formation of vias is carried out on the surface of the substrate.

Since no dimple is formed on the second surface of the substrate, on which the metal posts are formed, there is no irregularity formed on the surface of the PSR. Thus, a flat PSR surface is provided.

In the method of manufacturing a circuit board with metal posts according to the exemplary embodiments, processing or treatment is carried out only for one surface of the substrate until the metal posts are formed through etching. Accordingly, it may be possible to carry out processing or treatment for two substrates in a state in which the two substrates are bonded to each other via a separable intermediate film, to form a double substrate structure. Thus, an enhancement in productivity is achieved.

While exemplary embodiments have been particularly shown and described above, those skilled in the art will appreciate that various changes may be made therein without departing from the principles and spirit of the inventive concept as defined by the following claims.

What is claimed is:

1. A method for manufacturing a circuit board provided with metal posts formed on at least one surface of the circuit board, comprising:
preparing a substrate comprising a conductive material;
performing a first selective etching on a first surface of the substrate in regions corresponding to insulating portions of a first circuit pattern;
laminating a first insulating layer over the first surface of the substrate; and
performing a second etching on a second surface opposite of the first surface of the substrate thereby forming the metal posts and the first circuit.

2. The method according to claim 1, further comprising:
forming a second circuit pattern on the first surface of the substrate through an additive method between the laminating of the first insulating layer and the performing of the second etching.

3. The method according to claim 1, further comprising:
forming a second circuit pattern on the first surface of the substrate through an additive method, after the performing of the second etching.

4. The method according to claim 2, further comprising:
forming vias extending through the first insulating layer before the forming of the second circuit pattern.

5. The method according to claim 3, further comprising:
forming vias extending through the first insulating layer, before the forming of the second circuit pattern.

6. The method according to claim 1, wherein the laminating the first insulating layer comprises forming the first insulating layer and a first conductive layer over the primarily-etched surface of the substrate,
further comprising:
forming a second circuit pattern on the first surface of the substrate through a subtractive method.

7. The method according to claim 6, wherein the first conductive layer is formed simultaneously with the first insulating layer through a lamination method or is formed over the first surface of the substrate through electroless plating.

8. The method according to claim 6, further comprising:
forming a second circuit pattern on the first surface of the substrate through a subtractive method between the laminating of the first insulating layer and the performing of the second etching.

9. The method according to claim 6, further comprising:
forming a second circuit pattern on the first surface of the substrate through a subtractive method after the performing of the second etching.

10. The method according to claim 6, wherein the performing of the second etching comprises etching the first and second surfaces of the substrate to form the metal posts, the first circuit pattern, and the second circuit pattern.

11. The method according to claim 10, wherein the performing of the second etching comprises:
forming photoresist layers over the surfaces of the substrate;
patterning the photoresist layers through selective exposure and development to correspond to the metal posts and the second circuit pattern; and
performing a third etching on the surfaces of the substrate in regions exposed through the photoresist layers to form the metal posts, the first circuit pattern and the second circuit pattern.

12. The method according to claim 11, wherein the forming the photoresist layers comprises:
forming one of the photoresist layers over the second surface of the substrate;
performing electrolytic plating over the first surface of the substrate; and
forming the other of the photoresist layers over the plated surface of the substrate.

13. The method according to claim 11, wherein the performing of the second etching further comprises:
simultaneously removing the photoresist layers.

14. The method according to claim 8, further comprising:
forming vias extending through the first conductive layer and the first insulating layer before the forming of the second circuit pattern.

15. The method according to claim 9, further comprising:
forming vias extending through the first conductive layer and the first insulating layer before the forming of the second circuit pattern.

16. The method according to claim 10, further comprising:
forming vias extending through the first conductive layer and the first insulating layer before the forming of the second circuit pattern.

17. The method according to claim 2, further comprising:
laminating a second insulating layer over the first surface of the substrate; and
forming a third circuit pattern on the first surface of the substrate through an additive method.

18. The method according to claim 2, further comprising:
forming a second insulating layer and a second conductive layer over the first surface of the substrate; and
forming a third circuit pattern on the first surface of the substrate through a subtractive method.

19. A circuit board provided with metal posts formed on at least one surface of the circuit board, comprising:
a first circuit pattern formed at an inside the substrate, on which the metal posts are formed; and
an insulating layer disposed at an inside of the substrate formed with the first circuit pattern, the insulating layer protruding in regions corresponding to insulating portions of the first circuit pattern,
wherein the substrate is made of a conductive material, and the metal posts and the first circuit pattern are formed through etching of the surface of the substrate, on which the insulating layer has been laminated.

20. The circuit board according to claim 19, further comprising:
a second circuit pattern provided on a second surface opposite of the first surface of the substrate; and
via holes which extend from the second circuit pattern through the insulating layer.
